(19) United States
(12) Patent Application Publication
(10) Pub. No.: US 2010/0089319 A1
(43) Pub. Date: Apr. 15, 2010

(54) RF RETURN PATH FOR LARGE PLASMA PROCESSING CHAMBER

(75) Inventors: Carl A. Sorensen, Morgan Hill, CA (US); John M. White, Hayward, CA (US); Jozef Kudela, Sunnyvale, CA (US); Jonghoon Baek, San Jose, CA (US); Jriyan Jerry Chen, Santa Clara, CA (US); Steve McPherson, Menlo Park, CA (US); Soo Young Choi, Fremont, CA (US); Robin L. Tiner, Santa Cruz, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/576,991

(22) Filed: Oct. 9, 2009

Related U.S. Application Data
(60) Provisional application No. 61/104,254, filed on Oct. 9, 2008.
(60) Provisional application No. 61/114,747, filed on Nov. 14, 2008.

(51) Int. Cl. C23C 16/00

(52) U.S. Cl. 118/723 E

(57) ABSTRACT

A method and apparatus having a RF return path with low impedance coupling a substrate support to a chamber wall in a plasma processing system is provided. In one embodiment, a processing chamber includes a chamber body having a chamber sidewall, a bottom and a lid assembly supported by the chamber sidewall defining a processing region, a substrate support disposed in the processing region of the chamber body, a shadow frame disposed on an edge of the substrate support assembly, and a RF return path having a first end coupled to the shadow frame and a second end coupled to the chamber sidewall.

### CROSS-REFERENCE TO RELATED APPLICATIONS

This application claims benefit of U.S. Provisional Application Ser. No. 61/104,254 filed Oct. 9, 2008 (Attorney Docket No. APPM/13941L) and U.S. Provisional Application Ser. No. 61/114,747, filed Nov. 14, 2008 (Attorney Docket No. APPM/13757L), both of which are incorporated by reference in their entirety.

### BACKGROUND OF THE INVENTION

1. Field of the Invention

The embodiments of the invention generally relate to a method and apparatus for plasma processing a substrate, and more specifically, a plasma processing chamber having a RF return path with low impedance and the method for using the same.

2. Description of the Related Art

Liquid crystal displays (LCDs) or flat panels are commonly used for active matrix displays such as computers, touch panel devices, personal digital assistances (PDAs), cell phones, television monitors, and the like. Further, organic light emitting diodes (OLEDs) have also been widely used for flat panel displays. Generally, flat panels comprise two plates having a layer of liquid crystal material sandwiched therebetween. At least one of the plates includes at least one conductive film disposed thereon that is coupled to a power source. Power, supplied to the conductive film from the power supply, changes the orientation of the crystal material, creating a patterned display.

In order to manufacture these displays, a substrate, such as a glass or polymer workpiece, is typically subjected to a plurality of sequential processes to create devices, conductors and insulators on the substrate. Each of these processes is generally performed in a process chamber configured to perform a single step of the production process. In order to efficiently complete the entire sequence of processing steps, a number of process chambers are typically coupled to a transfer chamber that houses a robot to facilitate transfer of the substrate between the process chambers. One example of a processing platform having this configuration is generally known as a cluster tool, examples of which are the families of AKT plasma enhanced chemical vapor deposing (PECVD) processing platforms available from AKT America, Inc., of Santa Clara, Calif.

As demand for flat panels has increased, so has the demand for larger sized substrates. For example, large area substrates utilized for flat panel fabrication have increased in area from 550 mm by 650 mm to over 4 square meters in just a few years and are envisioned to continue to increase in size in the near future. This growth in the size of the large area substrates has presented new challenges in handling and production. For example, the larger surface area of the substrates requires increased RF return capacity of the substrate supports for efficient RF return to the RF generation source. On conventional systems, a plurality of flexible RF return paths are used, wherein each RF return path has a first end coupled to the substrate support and a second end coupled to a chamber bottom. Since the substrate support must move between a lower substrate loading position and a higher deposition position in the processing chamber, the RF return path coupled to the substrate support requires a length sufficiently long enough to provide the flexibility needed to accommodate the substrate support movement. However, the increase in substrate and chamber size has caused the length of the RF return path to increase as well. Longer RF return paths have increased impedance, thereby adversely lowering the RF return capability and efficiency of the RF return paths, resulting in high RF potentials between chamber components that may adversely cause unwanted arcing and/or plasma generation.

Therefore, there is a need for an improved plasma processing chamber having a RF return path with low impedance.

### SUMMARY OF THE INVENTION

A method and apparatus having a low impedance RF return path coupling a substrate support in a plasma processing system is provided. In one embodiment, a processing chamber includes a chamber body having a chamber sidewall, a bottom and a lid assembly supported by the chamber sidewall defining a processing region, a substrate support disposed in the processing region of the chamber body, a shadow frame disposed on an edge of the substrate support assembly, and a flexible RF return path having a first end coupled to the shadow frame and a second end coupled to the chamber sidewall.

In another embodiment, a processing chamber includes a chamber body having a chamber sidewall, a bottom and a lid assembly supported by the chamber sidewall defining a processing region, a substrate support assembly disposed in the processing region of the chamber body, an extension block attached to a bottom surface of the substrate support assembly and extending outward from an outer perimeter of the substrate support assembly, a ground frame disposed in the processing chamber sized to engage the extension block when the substrate support assembly is in an elevated position, and a RF return path having a first end coupled to the ground frame and a second end coupled to the chamber sidewall.

In another embodiment, a processing chamber includes a chamber body having a chamber sidewall, a bottom and a lid assembly supported by the chamber sidewall defining a processing region, a substrate support assembly disposed in the processing region of the chamber body movable between a first position and a second position, a shadow frame disposed approximate an edge of the substrate support assembly, a shadow-frame support coupled to the chamber body and sized to support the shadow frame when the shadow support assembly is in the second position, and a RF return path having a first end coupled to the ground frame and a second end coupled to the chamber sidewall, wherein the second end of the RF turn path is coupled to the chamber sidewall through an insulator.

In yet another embodiment, the processing chamber includes a chamber body having a chamber sidewall, a bottom and a lid assembly supported by the chamber sidewall defining a processing region, a backing plate disposed in the chamber body below the lid assembly, a substrate support disposed in the processing region of the chamber body, a RF return path having a first end coupled to the substrate support and a second end coupled to the chamber body, and one or more conductive leads having a plurality of contact points coupled to a perimeter and above the backing plate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a cross sectional view of one embodiment of a plasma enhanced chemical vapor deposition system having a RF return path;

FIG. 2 is an exploded view of the RF return path coupled to a substrate support disposed in the plasma enhanced chemical vapor deposition system of FIG. 1;

FIG. 3 is a cross sectional view of another embodiment of a plasma enhanced chemical vapor deposition system having a RF return path;

FIG. 4 is a cross sectional view of another embodiment of a plasma enhanced chemical vapor deposition system having a RF return path; and

FIG. 5 is a cross sectional view of another embodiment of a plasma enhanced chemical vapor deposition system having a RF return path;

FIG. 6A-D is a cross sectional view of another embodiment of a plasma enhanced chemical vapor deposition system having a RF return path;

FIG. 7 is a top view of the plasma enhanced chemical vapor deposition system having the RF return path depicted in FIG. 6A;

FIG. 8 is a side cross-sectional view of a chamber;

FIG. 9 is a side cross-sectional view of a chamber according to one embodiment of the invention;

FIG. 10 is a side cross-sectional view of a chamber according to another embodiment of the invention; and

FIG. 11 is a side cross-sectional view of a chamber according to another embodiment of the invention.

To facilitate understanding, identical reference numerals have been used, where possible, to designate identical elements that are common to the figures. It is to be noted, however, that the appended drawings illustrate only typical embodiments of this invention and are therefore not to be considered limiting of its scope, for the invention may admit to other equally effective embodiments.

### DETAILED DESCRIPTION

The invention generally relates to a plasma processing chamber having a low impedance RF return path in a plasma processing system. The plasma processing chamber is configured to process a large area substrate using plasma in forming structures and devices on the large area substrate for use in the fabrication of liquid crystal displays (LCD's), flat panel displays, organic light emitting diodes (OLED's), or photovoltaic cells for solar cell arrays, and the like. Although the invention is illustratively described, shown and practiced within the large area substrate processing system, the invention may find utility in other plasma processing chambers where it is desirable to ensure that one or more RF return paths remain functioning at a level that facilitates acceptable processing within the chamber.

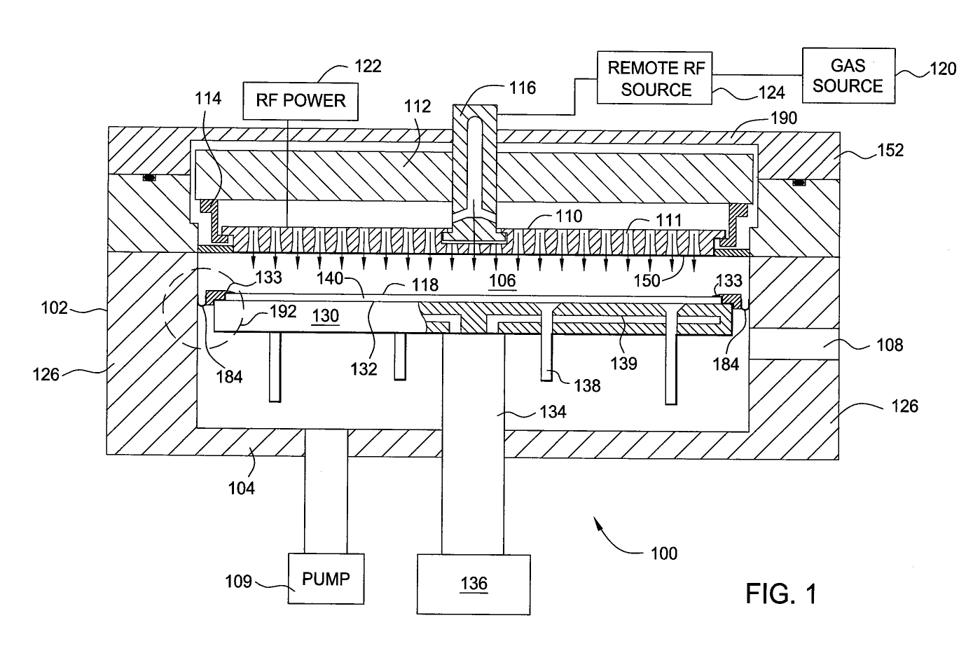

FIG. 1 is a cross sectional view of one embodiment of a plasma enhanced chemical vapor deposition chamber 100 having one embodiment of a flexible RF return path 184 utilized as part of an RF current return loop that returns RF current back to an RF source. The RF return path 184 is coupled between a substrate support assembly 130 and a chamber body 102, such as a chamber sidewall 126. It is contemplated that embodiments of the RF return path 184 and method for using the same described herein, along with derivations thereof, may be utilized in other processing systems, including those from other manufacturers.

The chamber 100 generally includes sidewalls 126 and a bottom 104 which bound a process volume 106. The sidewalls 126 and bottom 104 of the chamber body 102 are typically fabricated from a unitary block of aluminum or other material compatible with process chemistries. A gas distribution plate 110, or called a diffusor, and substrate support assembly 130 are disposed in the process volume 106. A RF source 122 is coupled to an electrode at the top of the chamber, such as a backing plate 112 and/or gas distribution plate 110, to provide a RF power to create an electric field between the gas distribution plate 110 and the substrate support assembly 130. The electric field generates a plasma from the gases between the gas distribution plate 110 and the substrate support assembly 130 which are utilized to process the substrate disposed in the substrate support assembly 130. The process volume 106 is accessed through a valve 108 formed through the wall 126 such that a substrate 140 may be transferred into and out of the chamber 100. A vacuum pump 109 is coupled to the chamber 100 to maintain the process volume 106 at a desired pressure.

The substrate support assembly 130 includes a substrate receiving surface 132 and a stem 134. The substrate receiving surface 132 supports the substrate 140 while processing. The stem 134 is coupled to a lift system 136 which raises and lowers the substrate support assembly 130 between a lower substrate transfer position and a higher processing position (as shown in FIG. 1). The nominal spacing during deposition between the top surface of a substrate disposed on the substrate receiving surface 132 and the gas distribution plate 110 may generally vary between 200 mil and about 1,400 mil, such as between 400 mil and about 800 mil, or other distance across the gas distribution plate 110 to provide desired deposition results.

A shadow frame 133 is placed over a periphery of the substrate 140 when processing to prevent deposition on the edge of the substrate 140. Lift pins 138 are moveably disposed through the substrate support assembly 130 and adapted to space the substrate 140 from the substrate receiving surface 132. In one embodiment, the shadow frame 133 may be fabricated by a metal material, a ceramic material, or any suitable materials. In one embodiment, the shadow frame 133 is fabricated by a bare aluminum or a ceramic material. The substrate support assembly 130 may also include heating and/or cooling elements 139 utilized to maintain the substrate support assembly 130 at a desired temperature. In one embodiment, the heating and/or cooling elements 139 may be set to provide a substrate support assembly temperature during deposition of about 400 degrees Celsius or less, for example between about 100 degrees Celsius and about 400 degrees Celsius, or between about 150 degrees Celsius and about 300 degrees Celsius, such as about 200 degrees Celsius. In one embodiment, the substrate support assembly 130 has a polygonal plane area, for example, having four lateral sides.

In one embodiment, a plurality of RF return paths 184 are coupled to the substrate support assembly 130 to provide RF return path around the periphery of the substrate support assembly 130. The substrate support assembly 130 is normally coupled to the RF return paths 184 during processing to allow the RF current travel to the RF source therethrough. The RF return path 184 provides a low-impedance RF return path between the substrate support assembly 130 and RF power source 122, such as via a cable directly or through the chamber ground chassis.

In one embodiment, the RF ground path 184 are a plurality of flexible straps (two of which are shown in FIG. 1) coupled between the perimeter of the substrate support assembly 130 and the chamber sidewall 126. The RF return path 184 may be fabricated from titanium, aluminum, stainless steel, beryllium copper, a material coated with a conductive metallic coating, or other suitable RF conducting material. The RF return path 184 may be evenly or randomly distributed along the respective sides of the substrate support assembly 130.

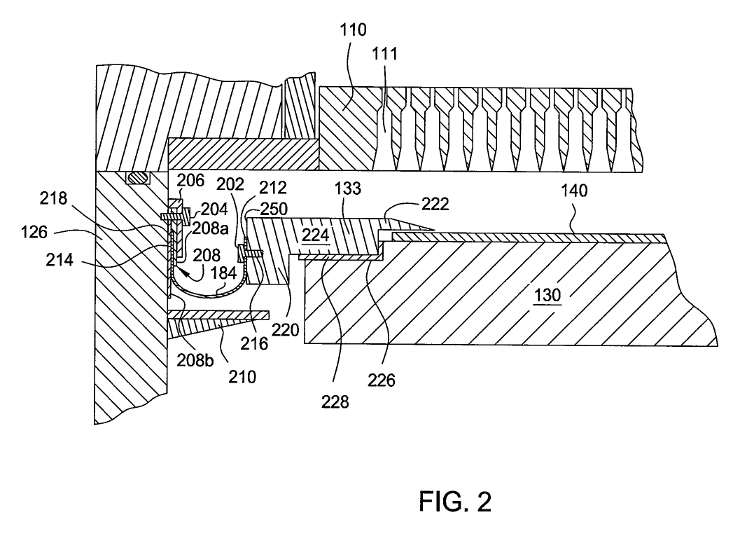

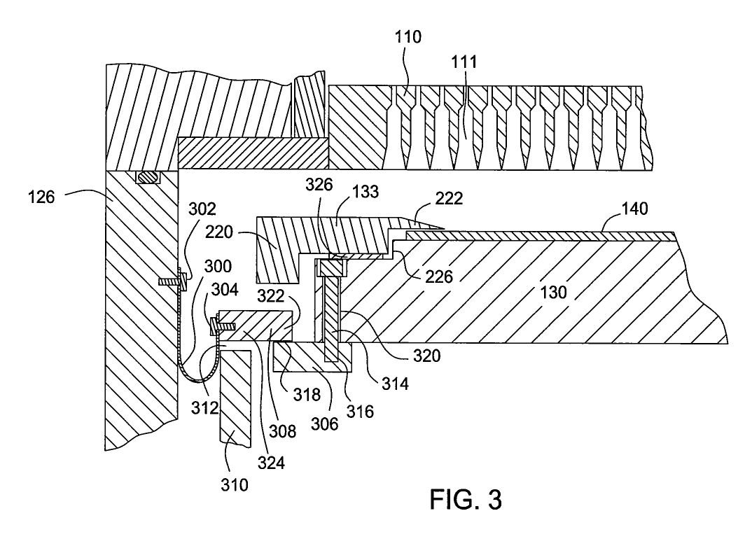

In one embodiment, the RF return path 184 has a first end coupled to the substrate support assembly 130 and a second end coupled to the chamber sidewall 126. The RF return path 184 may be coupled to the substrate support assembly 130 directly, through the shadow frame 133 and/or through other suitable RF conductors. An exploded view illustrating the RF return path 184 is coupled to the substrate support assembly 130 through the shadow frame 133, as indicated by circle 192, is discussed below with reference to FIG. 2. Other configurations for an RF return path are described further below with reference to FIGS. 3-5.

The gas distribution plate 110 is coupled to a backing plate 112 at its periphery by a suspension 114. A lid assembly 190 is supported by the sidewalls 126 of the processing chamber 100 and may be removed to service the interior of the chamber body 102. The lid assembly 190 is generally comprised of aluminum. The gas distribution plate 110 is coupled to the backing plate 112 by one or more center supports 116 to help prevent sag and/or controls the straightness/curvature of the gas distribution plate 110. In one embodiment, the gas distribution plate 110 may be in different configurations with different dimensions. In an exemplary embodiment, the gas distribution plate 110 is a quadrilateral gas distribution plate. The gas distribution plate 110 has a downstream surface 150 having a plurality of apertures 111 formed therein facing an upper surface 118 of the substrate 140 disposed on the substrate support assembly 130. In one embodiment, the apertures 111 may have different shapes, numbers, densities, dimensions, and distributions across the gas distribution plate 110. The diameter of the apertures 111 may be selected between about 0.01 inch and about 1 inch. A gas source 120 is coupled to the backing plate 112 to provide gas through the backing plate 112, and then through the apertures 111 formed in the gas distribution plate 110 to the process volume 106.

The RF power source 122 is coupled to the backing plate 112 and/or to the gas distribution plate 110 to provide a RF power to create an electric field between the gas distribution plate 110 and the substrate support assembly 130 so that a plasma may be generated from the gases between the gas distribution plate 110 and the substrate support assembly 130. Various RF frequencies may be used, such as a frequency between about 0.3 MHz and about 200 MHz. In one embodiment the RF power source is provided at a frequency of 13.56 MHz. Examples of gas distribution plates are disclosed in U.S. Pat. No. 6,477,980 issued on Nov. 12, 2002 to White, et al., U.S. Publication No. 20050251990 published on Nov. 17, 2005 to Choi, et al., and U.S. Publication No. 2006/0060138 published on Mar. 23, 2006 to Keller, et al, which are all incorporated by reference in their entirety.

A remote plasma source 124, such as an inductively coupled remote plasma source, may also be coupled between the gas source 120 and the backing plate 112. Between processing substrates, a cleaning gas may be energized in the remote plasma source 124 to remotely provide plasma utilized to clean chamber components. The cleaning gas may be further excited by the RF power provided to the gas distribution plate 110 by the power source 122. Suitable cleaning gases include, but are not limited to, NF₃, F₂, and SF₆. Examples of remote plasma sources are disclosed in U.S. Pat. No. 5,788,778 issued Aug. 4, 1998 to Shang et al, which is incorporated by reference.

FIG. 2 depicts an exploded view of one embodiment of the RF return path 184. The RF return path 184 has sufficient flexibility to allow the substrate support assembly 130 to change elevations between the lower substrate transfer position and the higher processing position, as described with reference to FIG. 1. In one embodiment, the RF return path 184 is a flexible RF conductive strap.

The shadow frame 133 has a lip 222 extending from a body 224 of the shadow frame 133 to cover the perimeter of the substrate 140 from deposition during processing. The shadow frame body 224 rests on a step 226 formed on a peripheral edge of the substrate support assembly 130. A ceramic insulator 228 is disposed between the shadow frame body 224 and the peripheral edge of the substrate support assembly 130 to increase capacitance and provide a good insulation between the shadow frame 133 and the substrate support assembly 130. The insulator 228 isolates the shadow frame floating potential from DC ground so that the likelihood potential plasma or electric arcing during processing may be reduced and eliminated. The shadow frame 133 further includes a projection 220 extending from a bottom portion of the shadow frame body 224. The projection 220 may be a plurality or discreet tabs or a continuous rim. A shadow-frame support 210 is attached to the chamber sidewall 126 in a location positioned to receive the projection 220 of the shadow frame 133. When the substrate support assembly 130 is lowered to the lower substrate transfer position, the shadow frame 133 is lowered along with the substrate support assembly 130 until the shadow-frame support 210 engages the shadow frame 133 and lifts it from the substrate support assembly 130 as the substrate support assembly 130 continues downward. The shadow-frame support 210 constrains the shadow frame movement within a predetermined vertical range so that the RF return path 184 coupled to the shadow frame 133 requires only a minimal amount of flexibility. In this manner, the length of the RF return path 184 can be short, as compared to grounding straps of the prior art. The short RF return path 184 advantageously provides low impedance which effectively conducts RF current while mitigating high potentials between chamber components.

In one embodiment, the RF return path 184 has a first end 212 and a second end 214. The first end 212 is coupled to an outer wall 250 of the shadow frame 133, for example, by a fastener 202, a clamp or other method that maintains electrical connection between the shadow frame 133 and RF return path 184. In the embodiment depicted in FIG. 2, the fastener 202 is screwed into a threaded hole 216 to couple the RF return path 184 to the shadow frame 133. It is contemplated that adhesives, clamps or other methods that maintain electrical connection between the chamber sidewall 126 and RF return path 184 may be utilized. The second end 214 of the RF return path 184 has a terminal 218 sandwiched between insulators 208 (shown as 208a and 208b). The insulators 208 may also be covered by a protection cover 206 and be attached to the chamber wall 126 via a fastener 204. The insulators 208 serve as a capacitor that prevents DC current from traveling through the strap. The insulators 208 also increase the strap capacitance and reduce or minimize the RF impedance of the RF return path 184. Additionally, the insulators 208 also isolate the floating DC potential generated from the shadow frame 133 from ground to avoid arcs between the shadow frame 130 and the substrate 140. In one embodiment, the insulators 208 may be fabricated from a durable ceramic material that provides good insulation and side capacitance. In one embodiment, the ceramic insulations are fabricated by a high-k dielectric materials, Al₂O₃ and the like. It is also contemplated that the insulators 208 may not be used.

The shadow-frame support 210 is attached to the chamber sidewall 126 below the insulators 208 to receive the shadow frame 133 when the substrate support assembly 130 is lowered to the lower substrate transfer position, as discussed above. During substrate processing, statistic charges and/or RF current from the substrate surface is passed through shadow frame 133 and the RF return path 184 to insulators 208 and further to chamber wall 126, thereby forming a RF return path (e.g., a close loop) back to the gas distribution plate 110.

By positioning the RF return path 184 between the shadow frame 133 to chamber sidewall 126, the required length of the RF return path 184 is much shorter, as compared to conventional designs coupling the substrate support assembly 130 to chamber bottom, so that the impedance of the RF return path 184 is substantially reduced. An overly long length of a RF return path could result in high impedance which may cause a potential difference cross the substrate support assembly. The presence of a high potential difference across the substrate support assembly 130 may adversely affect deposition uniformity. Furthermore, high impedance of the RF return paths may render the RF return path ineffective or insufficient RF return, so that plasma and/or static charges may not be efficiently removed from substrate surface but travel to the side, edge gap, and below the substrate support assembly 130, resulting in undesired deposition or plasma erosion on chamber components located in these areas, thereby reducing part service life and increasing possibility of particle contamination.

Furthermore, the insulators 208 positioned to the end of the RF return path 184 serves as a capacitor that increases the capacitance of the RF return path, thereby lowering the impedance of the RF return path. It is contemplated that insulators 208 may not be necessary coupled to the end of the RF return path 184. The insulators 208 may be positioned in the front, middle, end or other suitable place along the strap of the RF return path 184 to increase capacitance of the RF return path 184. Since the impedance of a capacitor is inversely proportional to its capacitance, maintaining high capacitance of the insulators 208 disposed and/or connected to the RF return path 184 in series may lower the overall RF return path impedance. In this arrangement, the strap may serve as an inductor providing inductive reactance (e.g., impedance) while the ceramic insulator 208 may server as a capacitor providing capacitive impedance. As the inductor and capacitor have reactance of opposite signs, a proper arrangement of the strap and the ceramic insulator formed along the RF return path 184 may produce a compensated waveform, offset positive and negative electrical impedance, thereby providing low impedance, e.g., ideally to zero impedance, of the RF return path. Accordingly, by controlling the length of the RF return path, with optional insulators 208, and positioning the RF return path at a location above the substrate support assembly, an efficient RF current conductivity, low impedance while high conductive RF return path may be obtained and the unwanted arcing effect may be reduced or even eliminated.

In one embodiment, the RF return path 184 has a length between about 2 inch and about 20 inch and has a width between about 10 mm and about 50 mm. The number of the RF return path disposed around the substrate support assembly may be between about 4 and about 100. In one embodiment, the impedance of the RF return path 184 having a length of about 20 inch is about 36 Ohm.

FIG. 3 depicts another embodiment of a RF return path 300 coupling to the substrate support assembly 130 to the chamber wall 126. It is noted that the number of the RF return paths may be varied as needed to meet different hardware configurations and process requirements. Similar to the design described in FIGS. 1-2, the shadow frame 133 is disposed on the edge step 226 of a perimeter of the substrate support assembly 130. In one embodiment, the shadow frame 133 is fabricated by a bare aluminum or a ceramic material. An insulator 326 is disposed between the shadow frame 133 and the edge step 226 of the substrate support assembly 130 to isolate the shadow frame 133 from DC ground. The insulator 326 keeps the shadow frame 133 is a floating position from DC ground so that the likelihood of arcing between the substrate 140 and the shadow frame 133 may be reduced. A fastener 314 is passed through a hole 320 formed in the substrate support assembly 130 and screwed into a threaded hole 316 formed in an extension block 306. The fastener 314 is fabricated from a conductive material to maintain a good electrical connection from the substrate surface to the extension block 306.

In one embodiment, the extension block 306 is attached to a bottom surface of the substrate support assembly 130 and extending outward from an outer perimeter of the substrate support assembly 130. The extension block 306 may be in form of a frame-shaped plate disposed around perimeter of the substrate support assembly 130 from the substrate support assembly bottom surface. In another embodiment, the extension block 306 may be in the form of individual bars distributed around the pedestal assembly sized to allow a movable ground frame 308 to rest thereon when the pedestal assembly is lowered. In yet another embodiment, the extension block 306 may be in other forms configured to support the movable ground frame 308 to rest thereon when the pedestal assembly is lowered.

The movable ground frame 308 is sized so that an inner side 322 of the ground frame 308 can rest on the extension block 306 when the substrate support assembly 130 is elevated to the processing position. An outer side 324 of the ground frame 308 is sized to rest on a side pumping shield 310 when the substrate support assembly 130 is lowered to the transfer position. In one embodiment, the side pumping shield 310 may be any support structure disposed in the processing chamber utilized to support the ground frame 308. The ground frame 308 is moveable relative to the extension block 306 and the side pumping shield 310. The RF return path 300 has a first end coupled to the ground frame 308 by a first fastener 304 and a second end coupled to the chamber sidewall 126 by a second fastener 302. In one embodiment, the RF return path 300 is in form of a flexible RF conductive strap. Additionally, an isolator 208 may optionally be utilized.

In operation, when the substrate support assembly 130 along with the extension block 306 is elevated to a substrate processing position, as shown in FIG. 3, the extension block 306 lifts the ground frame 308 off the side pumping shield 310 (or other static support). As the ground frame 308 is not permanently fixed or attached to the side pumping shield 310, when the ground frame 308 is lifted to the processing position, a gap 312 is formed between the ground frame 308 and the side pumping shield 310. During substrate processing, statistic charges and/or RF current in the substrate support assembly 130 runs through the fastener 314 and the extension block 306 to the ground frame 308, then through RF return path 300 to chamber wall 126, thereby forming a portion of an RF return loop back to the RF source 122. The gap 312 formed between the ground frame 308 and the side pumping shield 310 constrains the current conducted from the ground frame 308 to the RF return path 300 and prevents the current from passing to the side pumping shield 310.

After completion of processing, the substrate support assembly 130 is lowered to the substrate transfer position. The extension block 306 is thus lowered along with the substrate support assembly 130 to the substrate transfer position. The ground frame 308 accordingly engages the side pumping shield 310 and is lifted off the extension block 306. As the substrate support assembly 130 continues to lower, the shadow frame 133 engages and rest on an upper surface of the first side 322 of the ground frame 308, thereby being lifted off the substrate support assembly 130. In one embodiment, the shadow frame 133, the fasteners 314, 302, 304, the extension block 306, the ground frame 308 and the RF return path 300 are fabricated from a conductive material, such as aluminum, copper, or other suitable alloys that facilitate conducting RF current from the substrate support assembly 130 through chamber wall 126 back to the RF source 122.

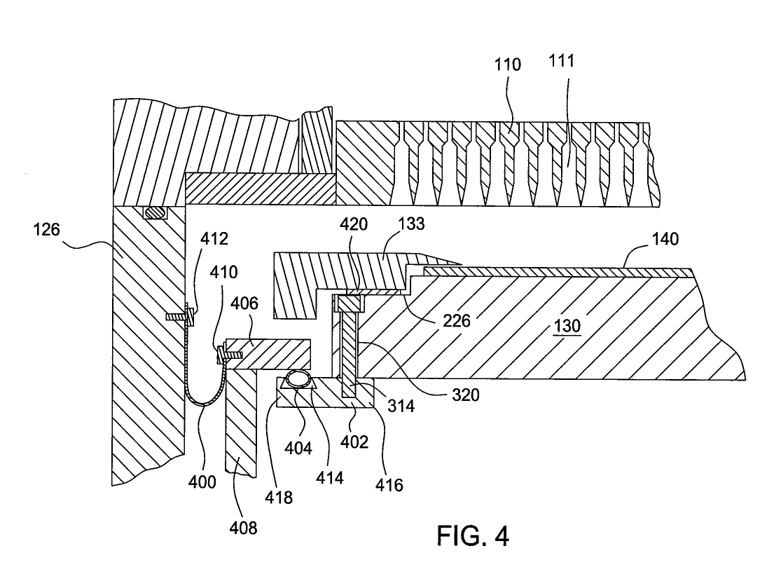

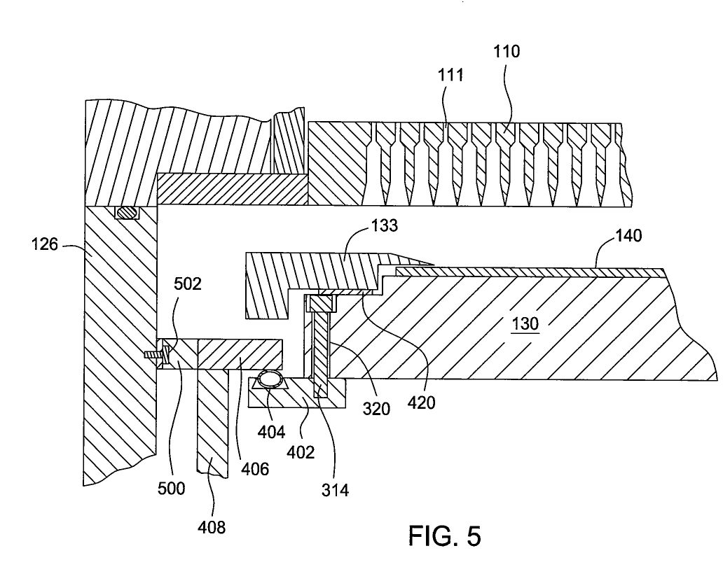

FIG. 4 depicts another embodiment of a RF return path 400. Similar to the configuration depicted in FIG. 3, the fastener 314 is passed through a hole 320 formed in the substrate support assembly 130 and screwed into a threaded hole formed in a first side 416 of an extension block 402. A second side 418 of the extension block 402 extends beyond the outer edge of the substrate support assembly 130. The second side 418 of the extension block 402 has a trench 414 formed in an upper surface of the extension block 402. A wound spiral wrap 404 is disposed in the trench 414 to improve the electrical conductance between the ground frame 406 and the extension block 402. In one embodiment, the wound spiral wrap 404 extends partially about the trench 414 and is resilient enough to retain its shape after multiple deflections. An insulator 420 is disposed between the shadow frame 133 and the edge step 226 of the substrate support assembly 130 to insulate the shadow frame 133 from the substrate support assembly 130. The insulator 420 between the shadow frame 133 and the substrate support assembly 130 prevents the shadow frame diminishes the likelihood of arcing during processing. A ground frame 406 has a first side that rests on the extension block 402 in contact with the wound spiral wrap 404 when the substrate support assembly 130 is elevated. The ground frame 406 has a second side coupled to a side pumping shield 408. A RF return path 400 has a first side coupled to the ground frame 406 by a first fastener 410 and a second side coupled to the chamber sidewall 126 by a second fastener 412. In one embodiment, the RF return path 400 is in form of a flexible RF conductive strap.

In this particular embodiment, the ground frame 406 is fixedly attached to the side pumping shield 408. The extension block 402 is moveable relative to the ground frame 406 while elevated and lowered between the upper substrate processing position and lower substrate transfer position. When the substrate support assembly 130 is elevated, the extension block 402 attached to the substrate support assembly 130 is lifted into contact with the ground frame 406 through the wound spiral wrap 404. The wound spiral wrap 404 provides a good interface that assists conducting RF current from the fastener 314 and the extension block 402 through the ground frame 406 and the RF return path 400 to chamber wall 126, thereby forming a RF return loop back to the RF power source 122. As the side pumping shield 408 is fixedly attached to the ground frame 406, the flexible wound spiral wrap 404 can accommodate a small difference in the elevation of the substrate support assembly 130 while maintaining good electrical and RF current contact between the ground frame 406 and the extension block 402. In one embodiment, the wound spiral wrap 404 is fabricated by a conductive material, such as aluminum, copper, or other suitable alloys that facilitate conducting RF current.

FIG. 5 depicts yet another embodiment of a RF return path 500. Similar to the configuration depicted in FIG. 4, the wound spiral wrap 404 is positioned in the extension block 402 to accommodate a vertical compliance while contacting with the ground frame 406. In this particular embodiment, instead of being in form of a flexible strap 400 as depicted in FIG. 4, the RF return path 500 is in form of a conductive bar fixedly coupled between the ground frame 406 and the chamber sidewall 126 through a fastener 502. The RF return path 500 may be adhered, bolted, screwed, or fastened to the ground frame 406 by any suitable means. As the conductive bar 500 is rigidly fixed between the chamber sidewall 126 and the ground frame 406, vertical accommodation for tolerance positioning of the substrate support assembly 130 is made by the wound spiral wrap 404. Alternatively, the RF return path 500 and the ground frame 406 may be formed as a unitary body having a first side attaching to the wall through the fastener 502 and a second side configured to rest on the wound spiral wrap 404.

The configuration of the RF return path 500 substantially prevents dislocation, friction and undesired relative and friction that might occur during repeated substrate support assembly movements over the course of substrate processing, thereby providing a cleaner processing environment. In one embodiment, the conductive bar 500 is fabricated by a conductive material, such as aluminum, copper, or other suitable alloys that facilitate conducting RF current.

In one embodiment, by utilizing insulators with high capacitance formed along the RF return path, low impedance along the overall RF return path may be obtained, enabling large RF currents to be carried. In addition to the utilization of the insulators along the RF return path, by the design of the RF return path between a chamber sidewall and a shadow frame and/or an extension block attached to a substrate support assembly, the length required for the RF return path is significantly shortened, as compared to conventional designs. Since the distance of the RF return path is much shorter than conventional techniques, the impedance of the RF return path is significantly lowered. Furthermore, the RF return path also provides large current carrying capacity, which is ideally suitable for use in large area processing applications. The relatively shorter travel distance of the RF return path provides low impedance and high conductivity for current carrying capacity, thereby resulting in a lower voltage difference across the substrate surface during processing. Low voltage difference reduces the likelihood of non-uniform plasma distribution and profile across the substrate surface, thereby providing a better uniformity of the film deposited on the substrate surface. Furthermore, as the RF return path may be substantially constrain the plasma, current, statistic charges, and electrons within the processing region above the substrate support assembly, the likelihood of unwanted deposition or active species erosion to the side or below the substrate support assembly may be substantially reduced, thereby extending the service life of components utilized in the lower region of the processing chamber. Additionally, the likelihood of particle contamination is reduced as well.

Additionally, by connecting the RF return path to the shadow frame, which is positioned at a periphery region of the substrate support assembly, the plasma distribution may be efficiently extended to the periphery region of the substrate support assembly, especially corners, e.g., edges, of the substrate support assembly. In conventional designs, plasma often can not efficiently and uniformly distribute to the periphery region of the substrate support assembly, thereby resulting in insufficient deposition on the substrate corners, e.g., edges. In the embodiment wherein the deposition process is configured to deposit a microcrystalline silicon layer on the substrate, the crystalline fraction of the deposited silicon film at the substrate corners, e.g., edges are often found insufficient and non-uniform to other regions, e.g., centers, or close to center regions, deposited on the substrate in conventional deposition technique. By utilizing the RF return path in the present application, extended plasma distribution efficiently provide sufficient plasma for deposition at periphery region, e.g., corners and edges, of the substrate support assembly so that the crystalline fraction formed at the deposited microcrystalline silicon film may be controlled and efficiently improved.

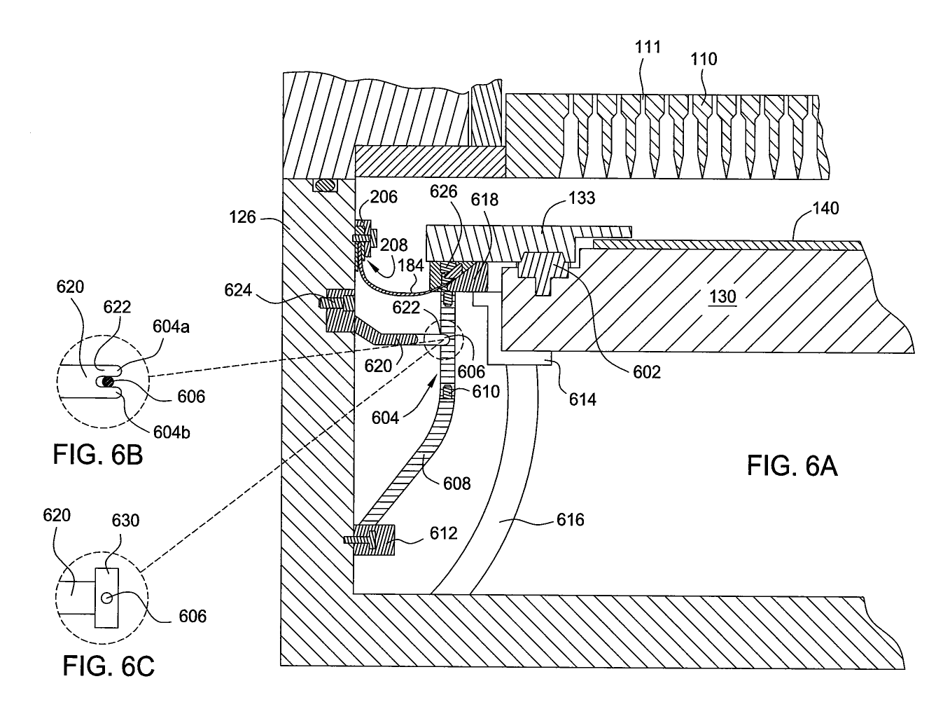

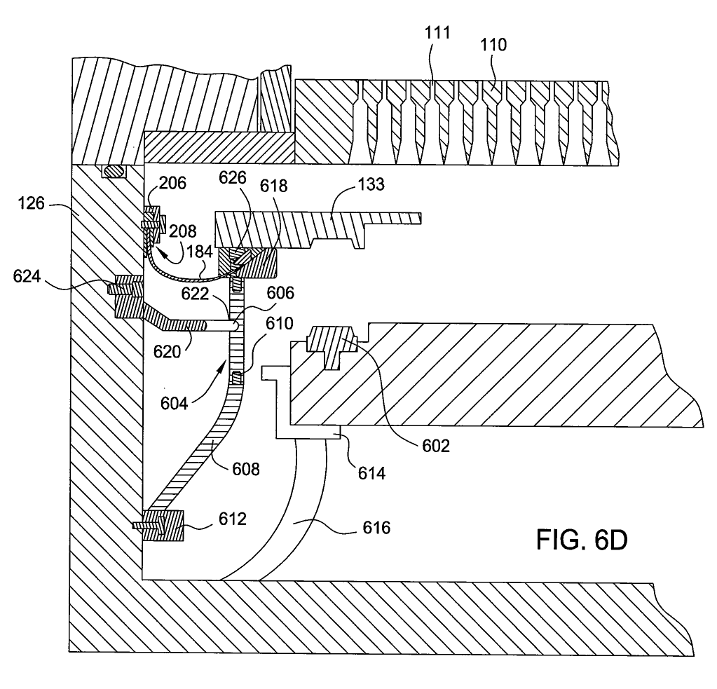

FIG. 6A depicts another embodiment of the RF return path 184, as depicted in FIG. 2, and a J-shape RF stick 604. The shadow frame 133 has a RF ground frame 618 attached to a bottom surface of the shadow frame 133. The RF return path 184 is attached between the chamber wall 126 and the RF ground frame 618. The RF return path 184 provides an inductive path for most of the energy and plasma in excess grounded and returned to the gas distribution plate or to ground. The J-shape RF stick 604 is attached to the end of the shadow frame 133 by a fastener 626 or other suitable fastening tools. In one embodiment, the J-shape RF stick 604 includes a rod 606 connected to an arc shape stick 608 through a fastener 610 or other suitable fastening tools. The J-shape RF stick 604 efficiently adds additional inductance to redirect excess energy or plasma to another portion of the chamber wall and away from the shadow frame 133 and upper portion of the chamber wall 126, which may minimize and eliminate arcing in the upper portion of the chamber wall 126 and the location close to the shadow frame 133 and the substrate.

A RF stick support 620 having a first end 624 attached to the chamber wall 126 and a second end 622 attached to the rod 606 of the J-shape RF stick 604. The second end 622 may have two tips, shown as 624a, 624b in FIG. 6B, defining an aperture allowing the rod 606 to pass therethrough. Alternatively, the RF stick support 620 have further includes a cap 630 that allows the rod 606 to pass therethrough, as shown in FIG. 6C. Alternatively, the RF stick support 620 may be configured to be in any form to support and hold the J-shape RF stick 604 fixedly in the processing chamber.

A ground frame lifter 614 is attached to a bottom side of the substrate support assembly 130 supporting the RF ground frame 618 attached to the shadow frame 133. A RF strap 616 is disposed between the ground frame lifter 614 to the chamber bottom. During processing, the ground frame lifter 614 supports the RF ground frame 618, creating a RF return path from the shadow frame 133 through the RF ground frame 618, ground frame lifter 614 further to the RF strap 616 to the chamber bottom. After processing, the substrate support assembly 130 is lowered to a substrate transfer position, as shown in FIG. 6D, the ground frame lifter 614 attached to the substrate support assembly 130 is lowered with the movement of the substrate support assembly 130. The RF strap 616 is flexibly bent to accommodate the actuation and movement of the substrate support assembly 130. When the substrate support assembly 130 is lowered down, the shadow frame 133 and the RF ground frame 618 are fixedly and immovably held by the J-shape RF stick 604 through the RF stick support 620 attached to the chamber wall 126, separating the shadow frame 133 and the RF ground frame 618 from the substrate support assembly 130 to facilitate substrate removed from the processing chamber.

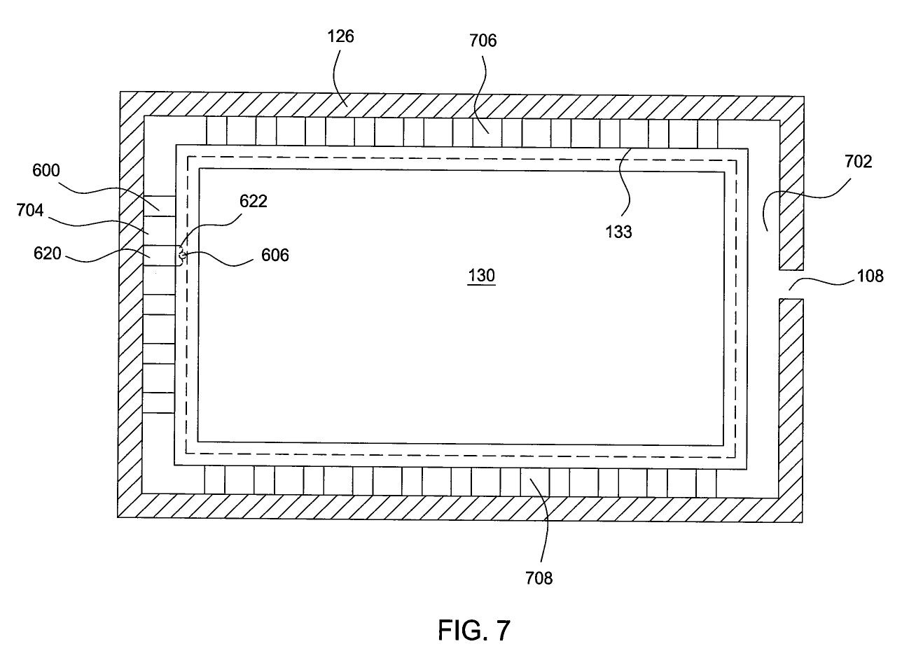

FIG. 7 depicts a top plain view of the substrate support assembly 130 disposed in the processing chamber. The shadow frame 133 is disposed on the periphery region of the substrate support assembly 130. A plurality of RF stick support 620 is disposed between the chamber wall 126 and the substrate support assembly 130. The RF stick support 620 is disposed around the periphery region of the substrate support assembly 130 except a region 702 defined between the chamber wall 126 having the slit valve 108 and the substrate support assembly 130. The RF stick support 620 positioned at the region 702 between the chamber wall 126 having the slit valve 108 and the substrate support assembly 130 may obstruct the movement of the robot into the processing chamber for substrate transfer. Accordingly, the RF stick support 620 may be configured to be disposed at other three sides, 706, 704, 708 along the periphery of the substrate support assembly 130.

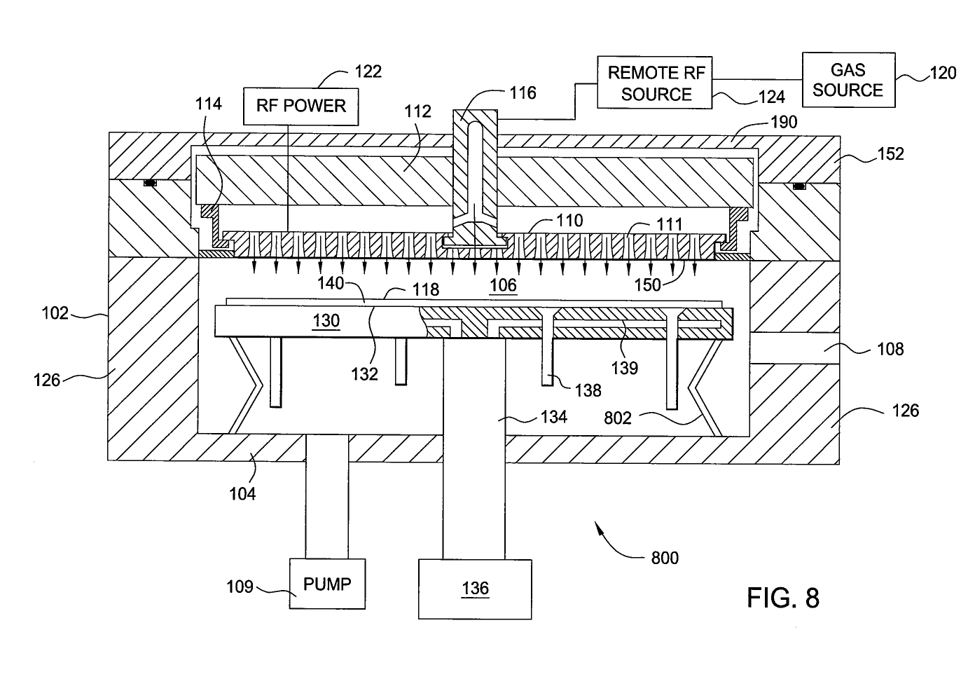

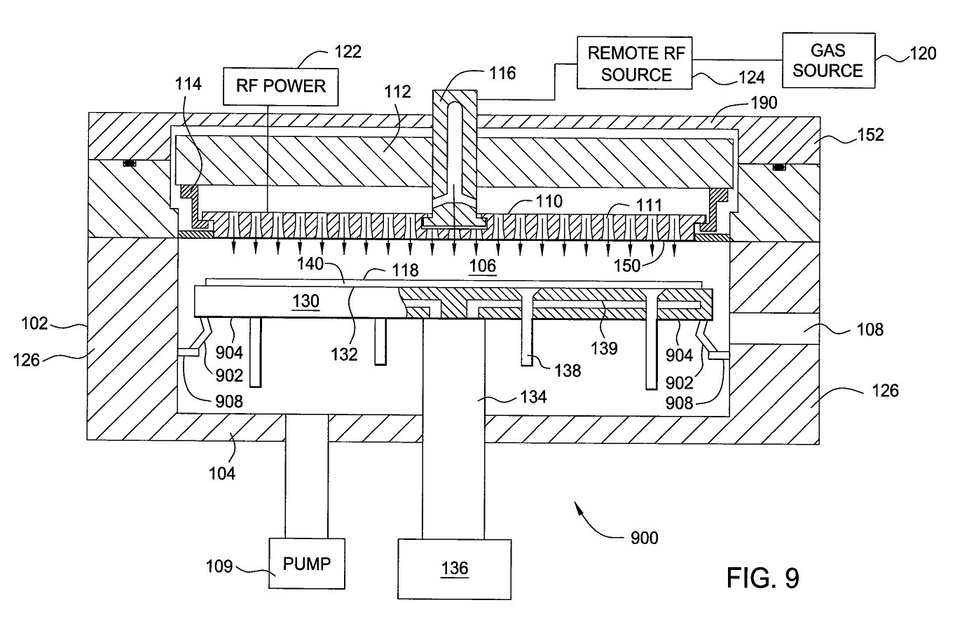

FIG. 8 depicts a chamber 800 having a RF return path 802 in form of ground straps disposed under the substrate support assembly to the chamber bottom 104. The functions of the RF return path 802 may be similar to the RF return path described above with referenced to FIGS. 1-7. FIG. 9 depicts a chamber 900 according to another embodiment of the invention. One or more RF return path 902 having one end coupling to a bottom surface 904 of the substrate support assembly 130 and another end coupling to the sidewall 126 of the chamber 900. The RF return path 902 is shorter than the RF return path 802 shown in the chamber of FIG. 8, which decreases the surface area of the RF return path 902 that is available for inductance of the energy from the RF power supplied from the backing plate 112 and the diffusor 110. Thus, the short RF return path 902 decrease inductance of energy and decrease the congregation of energy below the substrate support assembly 130. Accordingly, the short RF return path 902 advantageously provides low impedance which effectively conducts RF current while mitigating high potentials between chamber components.

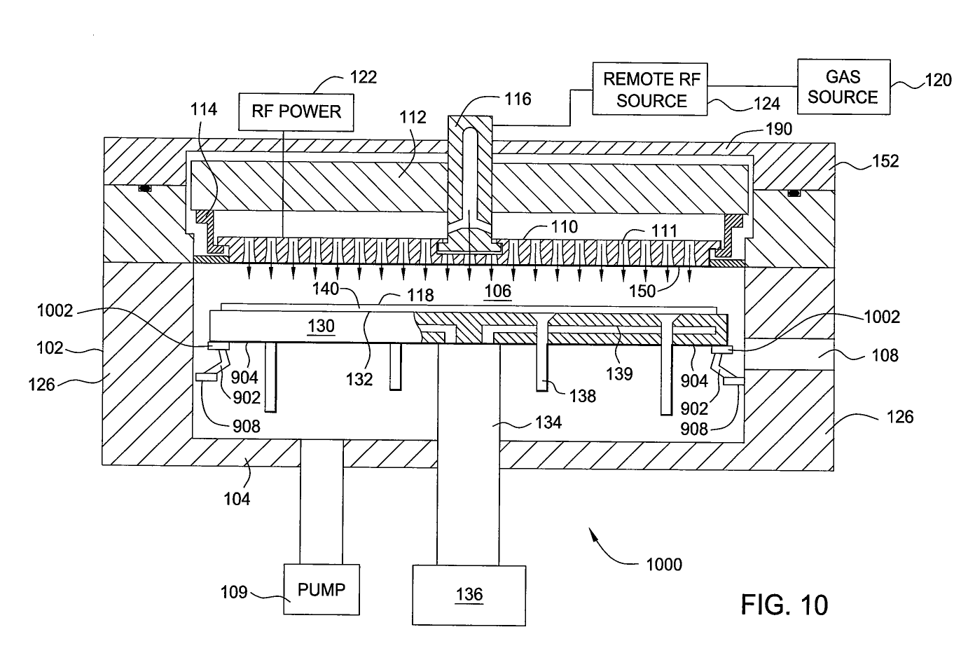

FIG. 10 depicts a chamber 1000 according to another embodiment of the invention. The chamber 1000 includes one or more RF return path 902 disposed in the chamber 1000. In this embodiment, a frame 1002 may have an upper side coupled to the lower surface 904 and/or a perimeter of the substrate support assembly 130 and a lower side coupled to an end of the RF return path 902. The frame 1002 extends outward from the substrate support assembly 130 and is in close proximity to the sidewall 126 of the chamber 1000. Additionally, the RF return path 902 is coupled to the substrate support assembly 130 through the frame 1002.

The frame 1002 provides a decrease in distance between the sidewall 126 which decreases the arcing distance between the substrate support assembly 130 and the sidewall 126. Additionally, the shorter RF return path 902 may decrease inductance of energy and decrease the congregation of energy below the substrate support assembly 130 as discussed above.

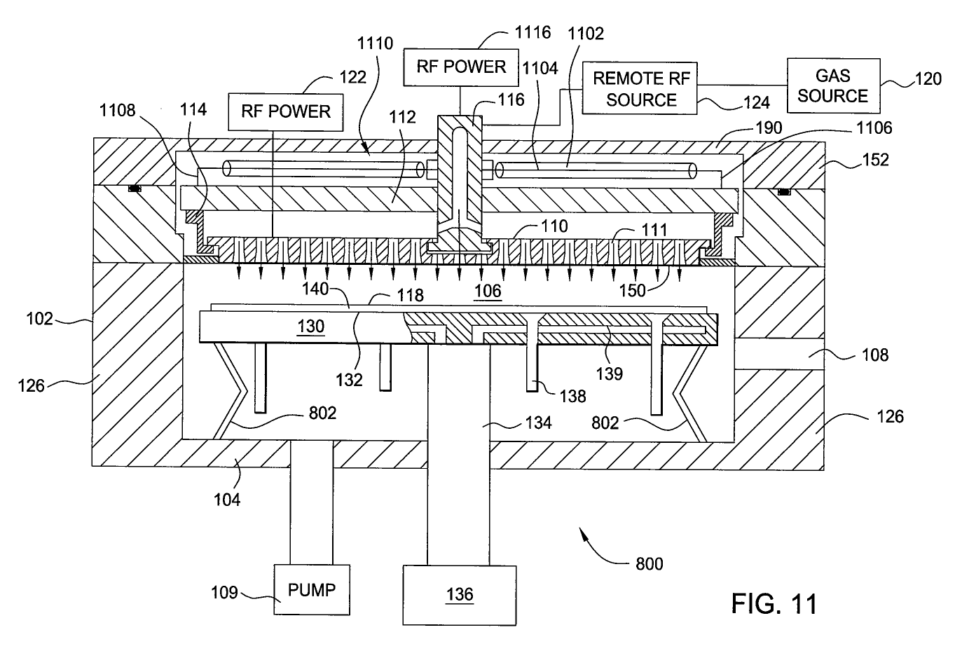

FIG. 11 shows a chamber 1100 according to another embodiment of the invention. The backing plate 112 and/or the diffusor 110 are coupled to a RF power source 1116, similar to the RF power source 112, by a split conductor 1110 that includes one or more conductive leads 1104. In the embodiment wherein the RF power source 1116 is coupled to the chamber 1100 through the center support 116, the RF power coupled to the diffusor 110 or the backing plate 112 may be removed or eliminated as needed. The one or more conductive leads 1104 provide energy from RF power source 1116 to be connected to the backing plate 112 at multiple connection points 1106, 1108 about the perimeter of the backing plate 112. The substrate support assembly 130 is coupled to the chamber body 102 by one or more RF return paths 802, as described in FIG. 8. In this embodiment, each of the conductive leads 1104 includes a length that substantially spans half of a dimension of the backing plate 112. A shield 1102 is provided along the length of the conductive leads 1104 to decrease the inductance of the energy from the RF power source 1116 to the backing plate 112 along this length. The shield 1102 is shown as a tubular member disposed about a substantial portion of the conductive leads 1104. The shield 1102 provides lower inductance of the energy between the conductive leads 1104 and the backing plate 112 along the length of the conductive lead 1104 which effectively isolates energy to the connection points of the conductive leads 1104 and the backing plate 112.

It is noted that the RF return path (i.e. straps) described above with referenced to FIGS. 1-11 formed and attached to the sidewall 126 where the valve 108 is located extend beyond the edge of the valve 108 so as to prevent deposition or particles entry from the valve 108. In other three sides of the sidewall 126 of the chamber, the RF return path (i.e. straps) may be formed individually and are spaced in a space-apart relation to allow good gas flow and pumping efficiency of the chamber.

Thus, a method and apparatus having a RF return path with low impedance coupling a substrate support or shadow frame to a chamber wall in a plasma processing system is provided. Advantageously, the low impedance RF return path provides a large current carrying capacity. The non-uniformity of plasma distribution across the substrate surface is substantially eliminated and undesired deposition to substrate side or underneath the substrate support assembly is therefore reduced.

While the foregoing is directed to the preferred embodiment of the present invention, other and further embodiments of the invention may be devised without departing from the basic scope thereof, and the scope thereof is determined by the claims that follow.

What is claimed is:

1. A processing chamber, comprising:
a chamber body having a chamber sidewall, a bottom and a lid assembly supported by the chamber sidewall defining a processing region;
a substrate support disposed in the processing region of the chamber body;
a shadow frame disposed on an edge of the substrate support assembly; and
a RF return path having a first end coupled to the shadow frame and a second end coupled to the chamber sidewall.

2. The processing chamber of claim 1, wherein the RF return path comprises a flexible aluminum strap.

3. The processing chamber of claim 1, further comprising:
an insulator disposed between the second end of the RF return path and the chamber sidewall.

4. The processing chamber of claim 1 further comprising:
a ceramic insulator preventing DC current flow through the RF return path to the chamber sidewall.

5. The processing chamber of claim 3, wherein the insulator is ceramic and attached to the chamber sidewall and RF return path by a fastener.

6. The processing chamber of claim 5, further comprising:
a dielectric cover covering the ceramic insulator and the second end of the RF return path.

7. The processing chamber of claim 1, further comprising:
a ceramic insulator disposed between the shadow frame and the substrate support assembly.

8. The processing chamber of claim 1, further comprising:
a shadow-frame support attached to the chamber sidewall and positioned to support the shadow frame when the substrate support assembly is in a substrate transfer position.

9. A processing chamber, comprising:
a chamber body having a chamber sidewall, a bottom and a lid assembly supported by the chamber sidewall defining a processing region;
a substrate support assembly disposed in the processing region of the chamber body;
an extension block attached to a bottom surface of the substrate support assembly and extending outward from an outer perimeter of the substrate support assembly;
a ground frame disposed in the processing chamber sized to engage the extension block when the substrate support assembly is in an elevated position; and
a RF return path having a first end coupled to the ground frame and a second end coupled to the chamber sidewall.

10. The processing chamber of claim 9, further comprising:
a side pumping shield disposed in the processing chamber below the ground frame.

11. The processing chamber of claim 9, wherein the ground frame has a first side configured to engage with the extension block and a second side to be positioned on the side pumping shield.

12. The processing chamber of claim 9, wherein the ground frame is fixedly coupled to the side pumping shield.

13. The processing chamber of claim 9, further comprising:
a gap defined between the ground frame and the side pumping shield when the ground frame is support by the extension block when the substrate support assembly is in an elevated position.

14. The processing chamber of claim 9, wherein the RF return path is a flexible strap.

15. The processing chamber of claim 9, wherein the RF return path is a conductive bar.

16. The processing chamber of claim 9, wherein the extension block is coupled to the substrate support assembly through a fastener.

17. The processing chamber of claim 16, further comprising:
a shadow frame disposed on an edge of the substrate support assembly connected to the fastener disposed in the substrate support assembly.

18. The processing chamber of claim 9, further comprising:
a wound spiral wrap disposed in an upper surface of the extension block outward of the substrate support assembly.

19. The processing chamber of claim 17, further comprising:
an insulator disposed between the shadow frame and the substrate support assembly.

20. A processing chamber, comprising:
a chamber body having a chamber sidewall, a bottom and a lid assembly supported by the chamber sidewall defining a processing region;
a substrate support assembly disposed in the processing region of the chamber body movable between a first position and a second position;
a shadow frame disposed approximate an edge of the substrate support assembly;
a shadow-frame support coupled to the chamber body and sized to support the shadow frame when the shadow support assembly is in the second position;
a RF return path having a first end coupled to the ground frame and a second end coupled to the chamber sidewall; and
a first insulator preventing DC current from flowing through the a RF return path to the chamber sidewall.

21. The processing chamber of claim 20, wherein the RF return path is a flexible aluminum strap.

22. The processing chamber of claim 20, further comprising:
a second insulator disposed between the shadow frame and the substrate support assembly.

23. A processing chamber, comprising:
a chamber body having a chamber sidewall, a bottom and a lid assembly supported by the chamber sidewall defining a processing region;
a backing plate disposed in the chamber body below the lid assembly;
a substrate support disposed in the processing region of the chamber body;
a RF return path having a first end coupled to the substrate support and a second end coupled to the chamber body; and
one or more conductive leads having a plurality of contact points coupled to a perimeter and above the backing plate.

24. The processing chamber of claim 23, further comprising:
a shield disposed along the conductive leads coupled to the backing plate.

25. The processing chamber of claim 23, further comprising:
a RF power source coupled to the backing plate through the conductive leads disposed in the processing chamber.
